(19) United States
(12) Patent Application Publication
(10) Pub. No.: US 2011/0139484 A1
(43) Pub. Date: Jun. 16, 2011

(54) Hermetic Electrical Feedthrough

(75) Inventors: Kurt J. Koester, Los Angeles, CA (US); Timothy Beerling, San Francisco, CA (US)

(73) Assignee: ADVANCED BIONICS, LLC, Valencia, CA (US)

(21) Appl. No.: 12/963,367

(22) Filed: Dec. 8, 2010

Related U.S. Application Data
(60) Provisional application No. 61/286,700, filed on Dec. 15, 2009.

(51) Int. Cl. H01B 17/26; B05D 5/12; C25D 13/00; C25D 5/34; B32B 38/04; H05K 5/06

(52) U.S. Cl. 174/50.56; 174/151; 427/58; 204/471; 205/205; 156/256

(57) ABSTRACT

A method for fabricating a hermetic electrical feedthrough includes engraving a circuitous groove into a surface of an electrically conductive monolithic slab so that the interior of the circuitous groove forms a pin. A dielectric material is formed in the circuitous groove. The pin is then electrically isolated from the surrounding material and provides electrical access through the hermetic feedthrough.

### RELATED DOCUMENTS

The present application claims the benefit under 35 U.S.C. §119(e) of U.S. Provisional Application No. 61/286,700, entitled “Hermetic Electrical Feedthrough” filed Dec. 15, 2009, which is incorporated herein by reference in its entirety.

### BACKGROUND

Hermetically sealed cases can be used to isolate electronic devices from environmental contamination. To form electrical or physical connections between the interior and the exterior of a hermetically sealed case, a hermetic feedthrough can be used. Ideally this hermetic feedthrough would maintain the integrity of the hermetic sealed case, while allowing electrical signals to pass through.

Many hermetically sealed devices are designed to be as small as possible to better perform their intended function. For example, many medical technologies make use of hermetically sealed implants to protect implanted electronics from body fluids and the patient from materials that are not biocompatible. Typically it is desirable to reduce the size of medical implants as much as possible to make the implants less prone to damage, easier to implant, and more comfortable for the patient. The size and reliability of the hermetic feedthrough can become a limiting design factor in smaller implants.

### BRIEF DESCRIPTION OF THE DRAWINGS

The accompanying drawings illustrate various embodiments of the principles described herein and are a part of the specification. The illustrated embodiments are merely examples and do not limit the scope of the claims.

FIG. 1 is a diagram showing an illustrative hermetically sealed device, according to one embodiment of principles described herein.

FIGS. 2A and 2B are diagrams showing an illustrative step in the fabrication of an electrical feedthrough, according to one embodiment of principles described herein.

FIGS. 3A and 3B are diagrams showing an illustrative step in the fabrication of an electrical feedthrough, according to one embodiment of principles described herein.

FIGS. 4A and 4B are diagrams showing an illustrative step in the fabrication of an electrical feedthrough, according to one embodiment of principles described herein.

FIGS. 5A-5C are diagrams showing illustrative steps for fabricating an electrical feedthrough using a deposition process, according to one embodiment of principles described herein.

FIG. 6 is a diagram of an illustrative hermetic feedthrough which has an extended insulating area, according to one embodiment of principles described herein.

FIG. 7 is a diagram of an illustrative hermetic feedthrough which has concentric pins, according to one embodiment of principles described herein.

FIG. 8 is a diagram of a portion of an illustrative hermetic feedthrough which incorporates a variety of pin geometries, according to one embodiment of principles described herein.

FIG. 9 is a diagram of an illustrative multilayer hermetic feedthrough, according to one embodiment of principles described herein.

FIG. 10 is a flowchart showing an illustrative method for fabricating an electrically isolated pin in a monolithic wafer, according to one embodiment of principles described herein.

Throughout the drawings, identical reference numbers designate similar, but not necessarily identical, elements.

### DETAILED DESCRIPTION

As mentioned above, a feedthrough is often used to form an electrical or physical connection between the interior and the exterior of a sealed case. A sealed case may be referred to as a hermetically sealed case if it is substantially impermeable to liquids and gasses. Hermetically sealed cases are used to protect electronic components from environmental contaminants. An electrical connection, called a hermetic feedthrough, is made between components exterior to the hermetically sealed case and electronic components inside the hermetically sealed case. This hermetic feedthrough maintains the integrity of the hermetically sealed case, while allowing electrical signals to pass through.

Many hermetically sealed devices are designed to be as small as possible to better perform their intended function. For example, many human implant technologies often make use of hermetically sealed devices. These hermetically sealed devices prevent body fluids from damaging electronic components contained within the device. The current trend is toward smaller and smaller implant devices. The smaller an implant device is, the less invasive the implant surgery can be. Furthermore, smaller implant devices may be more comfortable for patients than their larger counterparts. However, the smaller the device, the more difficult it may become to create an effective electrical feedthrough and hermetic seal.

According to one illustrative embodiment, a hermetic electrical feedthrough is created from a monolithic slab or wafer of conductive material. The feedthrough is created by fabricating at least one electrically isolated pin in the monolithic slab. The isolated pin may then be used as an electrical feedthrough. According to one illustrative embodiment, a circuitous groove is engraved into a monolithic metallic slab. The groove is engraved less than all the way through to the other side of the metallic slab. A dielectric material may then be placed within the groove. The bottom of the metallic slab may then be ground down until the dielectric material is exposed. This process leaves an electrically isolated metallic pin in the monolithic slab while maintaining its hermetic integrity. This metallic pin can then be used to carry electrical signals through the hermetic seal to interior electronics.

In many cases, multiple pins may be formed in a single monolithic slab. Each pin may carry a separate electrical signal through the slab. Therefore, it is important that the pins are electrically isolated from other pins. Electrical feedthroughs embodying principles described herein may allow for thinner cases for hermetically sealed devices.

In the following description, for purposes of explanation, numerous specific details are set forth in order to provide a thorough understanding of the present systems and methods. It will be apparent, however, to one skilled in the art that the present apparatus, systems and methods may be practiced without these specific details. Reference in the specification to “an embodiment,” “an example,” or similar language means that a particular feature, structure, or characteristic described in connection with the embodiment or example is included in at least that one embodiment, but not necessarily in other embodiments. The various instances of the phrase “in one embodiment” or similar phrases in various places in the specification are not necessarily all referring to the same embodiment.

Throughout this specification and in the appended claims, the term “circuitous groove” is to be broadly interpreted as a groove that forms a closed shape such that a point within the shape cannot be traced to a point outside the shape without crossing over the groove.

As used in the specification and appended claims, the term “pin” refers to an electrically conductive channel between the exterior and interior of a hermetic feedthrough. A pin may have a wide variety of shapes including circular, square, rectangular, elliptical, irregular, or other shapes. Further, in some embodiments such as co-axial feedthroughs, pins may be nested within other pins.

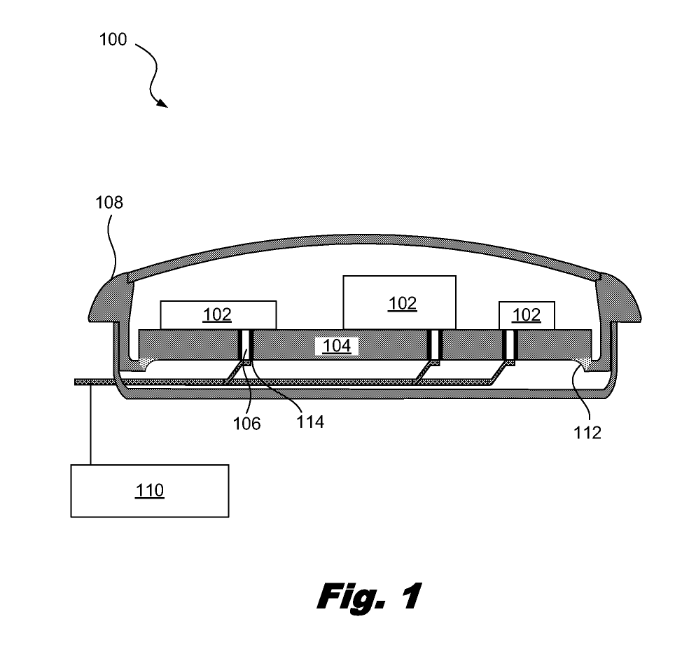

Referring now to the figures, FIG. 1 is a diagram showing an illustrative hermetically sealed device (100). According to one illustrative embodiment, a hermetically sealed device (100) may include an outer casing (108), a feedthrough (104) that includes a number of pins (106) electrically isolated by dielectric layers (114), internal electrical components (102), and external electrical circuitry (110).

The outer casing (108) of the hermetically sealed device (100) may be made from a variety of materials. For example, the outer case (108) may be formed from metals, ceramics, crystalline structures, composites, or other suitable materials. In some embodiments, the outer case (108) is formed from titanium or stainless steel. The outer casing may be formed from a single piece of material or may include multiple elements. The multiple pieces may be connected through a variety of methods including, but not limited to, brazing, laser welding, or bonding.

As mentioned above, an electrical feedthrough (104) may be used to provide an electrical connection between the interior and the exterior of a hermetically sealed case (100). These feedthroughs may be used to transfer power or data signals between interior electrical components (102) and external electrical circuitry (110). A hermetically sealed case (100) may have several feedthroughs. In some embodiments, the feedthrough may also provide optical transmission and channels which allow for the controlled flow of vapor or fluid.

According to one illustrative embodiment, the hermetic feedthrough (104) may be constructed from the same material as the outer case (108). For example, the outer case (108) and the hermetic feedthrough (104) may be made from titanium or titanium alloys. Laser welding may create a sealed joint (112) between the hermetic feedthrough (104) and the outer case (108).

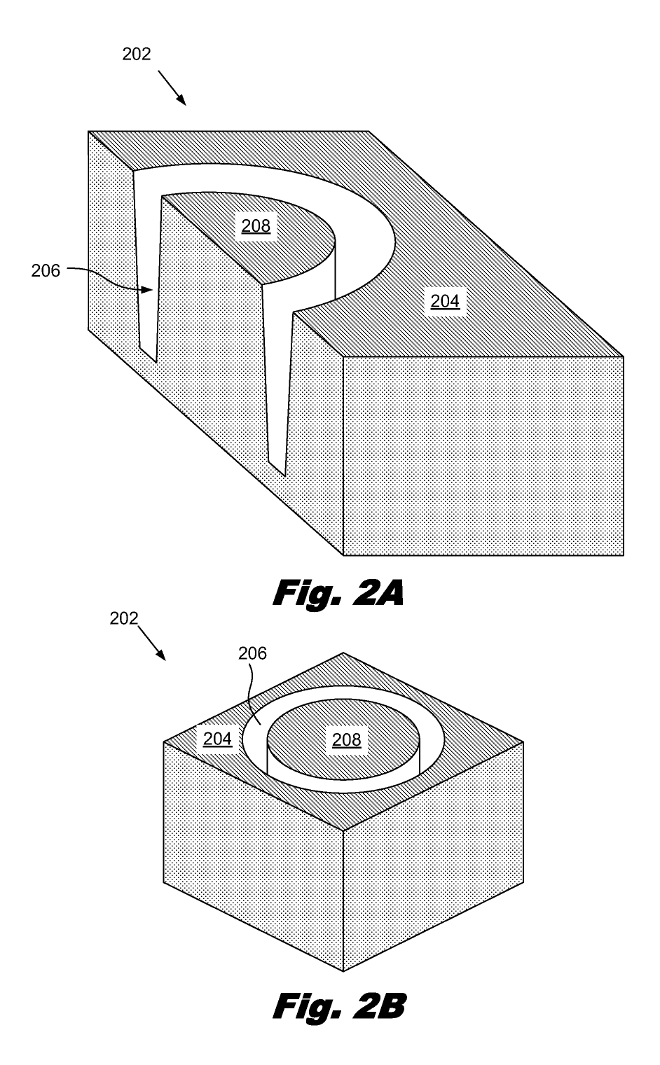

As mentioned above, it is important that a hermetic feedthrough provide a good electrical connection with interior electrical components while maintaining the integrity of the hermetic seal. The applicant has discovered a method for forming a hermetic feedthrough which creates the desired electrical connection while maintaining a strong hermetic seal. FIGS. 2A and 2B are perspective views of monolithic slab (202) wherein a circuitous groove (206) has been engraved. The monolithic slab may have a variety of shapes, thicknesses, and compositions as best suit the particular application. For example, the monolithic slab (202) may be formed from an electrically conductive metallic material, ceramic, composite, or other suitable material. In one embodiment, the monolithic slab (202) may be formed from titanium or a titanium alloy. The geometry, thickness, and composition of the monolithic slab (202) may be selected such that the hermetic feedthrough is able to withstand stresses, strains, impacts, and other loading conditions experienced by the hermetically sealed device. According to one illustrative embodiment, a titanium feedthrough may have a thickness between 0.008 inches and 0.040 inches. In some embodiments, monolithic slab (202) may be formed into a wafer which produces multiple hermetic feedthroughs.

A first step in forming a hermetic feedthrough from the monolithic slab (202) may include engraving a circuitous groove (206) in a surface (204) of the monolithic slab (202). The circuitous groove makes a complete circuit such that an upper surface of the interior region of the groove is isolated from the upper surface of the region outside the groove. The circuitous groove (206) may form a variety of shapes including, but not limited to, circular, elliptical, square, or rectangular. According to one illustrative embodiment, the groove (206) may be engraved to a depth that extends almost all the way though the monolithic slab (202). In other embodiments, the monolithic slab (202) may be backed by support structure and the groove may extend through the thickness of the monolithic slab (202). The groove (206) may or may not be consistent in width throughout its entire depth. For example, the width of the groove (206) may become narrower as the groove (206) becomes deeper. The groove (206) may be formed using a variety of processes including, but not limited to, laser ablation, dry etching, wet etching, lithography techniques, water jet, or other suitable techniques. According to one illustrative embodiment, the monolithic slab is a titanium wafer which is dry etched using a chlorine species. Additionally or alternatively, the groove (206) may formed using laser ablation. The interior of the circuitous groove (206) may be referred to as the pin (208). The pin (208) is the region which will provide the electrical conductive pathway through the feedthrough. For example, circular pins with a diameter of approximately 250 microns can be formed using the above techniques. The diameter, shape, and density of the pins can be altered according to design and process constraints.

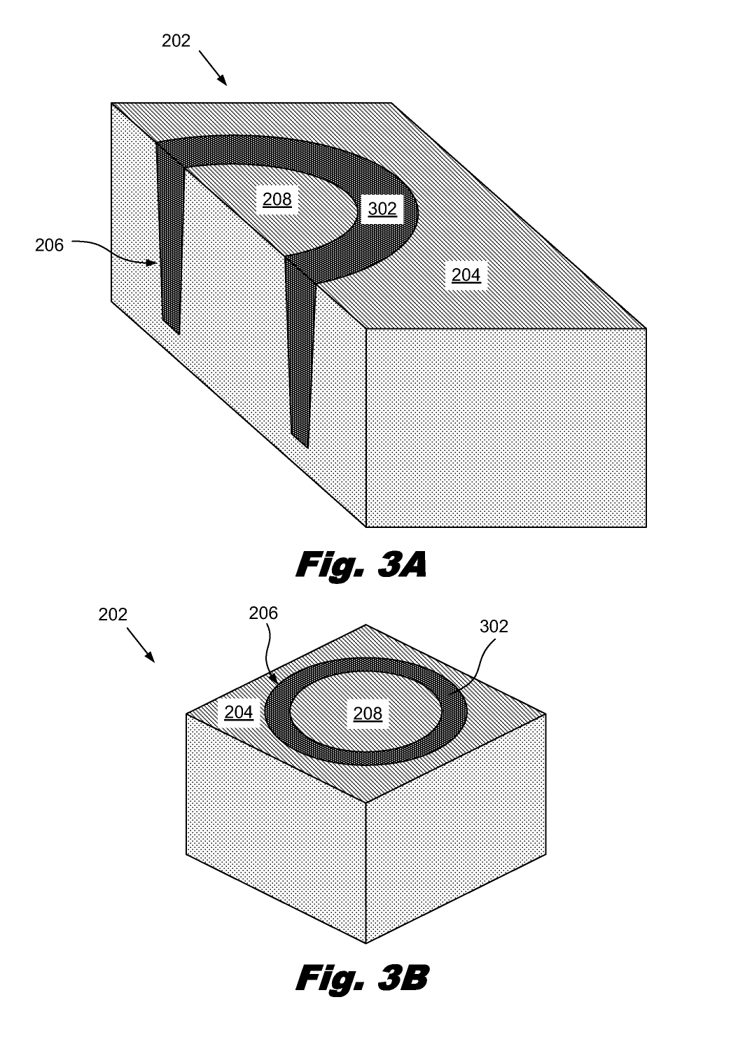

FIGS. 3A and 3B are diagrams showing an illustrative second step in the fabrication of the hermetic electrical feedthrough. According to one illustrative embodiment, this step includes forming a dielectric material (302) within the groove (206).

Similar to FIGS. 2A and 2B, FIG. 3A is an isometric view of a cross-sectional piece of a monolithic slab (202) in which a circuitous groove (206) has been engraved and dielectric material (302) formed therein. FIG. 3B is an isometric view of a piece of monolithic slab (202) having a circuitous groove (206) engraved therein and a dielectric material (302) formed within the groove (206).

The dielectric material may be formed within the circuitous groove (206) through a variety of methods including, but not limited to, anodizing, electrophoretic deposition, chemical vapor deposition, physical vapor deposition, spin coating, sol gel deposition, slurry/suspension casting, or other suitable deposition technique. The exact method used in a particular manufacturing instance may depend on a variety of factors including, but not limited to, the reliability of the resulting hermetic feedthrough, the dielectric material being deposited, the cost of the process and the intended purpose of the feedthrough. To further optimize the properties of the final feedthrough, additional processing steps may be utilized before and after the deposition of the dielectric layer, e.g., deposition of an adhesion promoting layer, annealing, sintering, etc.

According to one illustrative embodiment, the dielectric material may be deposited through an anodization process. Anodizing is a process whereby a metal-oxide layer is formed on top of a metal. A metal-oxide material is typically nonconductive. This nonconductive metal-oxide layer may be formed by placing the metallic monolithic slab into an electrolytic solution. An electrolytic solution is a substance containing free ions which make the solution electrically conductive. Electrolytic solutions which may be used include, but are not limited to, sulfuric acid (H₂SO₄), phosphoric acid (H₃PO₄), and oxalic acid (H₂C₂O₄). When anodizing a metal surface, the monolithic slab is used as the anode and an additional electrode is used to act as the cathode. With an applied voltage the anodic current causes an oxide to form on the surface of the metallic substrate. Components, such as the acids mentioned, can be used to influence the thickness and porosity of the oxide film that forms. If a porous oxide is formed, it will be desirable to fill the pores with a corrosion resistant dielectric to protect the underlying metal of the feedthrough and to ensure that it remains hermetic in aggressive environments. For example, if the monolithic slab (202) is titanium or a titanium alloy, the oxide metal layer may be titanium oxide. In general, a properly formed titanium oxide layer has sufficient structural strength and impermeability to seal the pin in place in the hermetic feedthrough.

Thermal oxidation of the conductive monolithic slab is another potential route to forming a stable and robust dielectric layer. For example, properly controlled oxidation of titanium results the formation of a titanium dioxide layer that is quite stable and exhibits good adhesion to the titanium substrate.

An electrophoretic deposition process involves the use of charged particles suspended within a solution. Under the presence of an electric field, these particles will migrate towards an electrically conductive body acting as either an anode or a cathode depending on the charge of the particles. With an applied voltage the charged particles migrate and adhere to the monolithic conductor and the resulting green body is sintered to yield a dense final part. In the present invention the particles are used to form the dielectric film that electrically isolates the pin. This dielectric film fills the groove (206), forming a hermetic seal between the pin and the surrounding slab material. Control of the deposition parameters will allow the chemistry and morphology of the feedthrough to be optimized to enhance the performance of the feedthrough.

Additionally or alternatively, a dielectric material may be formed in the groove by depositing a curable resin into the circuitous groove (206). Resins may be designed to be thermally curable or UltraViolet (UV) curable. Other similar types of methods may include the use of a sol gel. Sol gel methods involve the use of a gel-like solution which is solidified through a drying or firing process. A variety of other methods for forming a dielectric material by depositing a curable material into the circuitous groove (206) may be used.

After the dielectric material is in place, the bottom surface of the monolithic slab may be ground down to expose the deepest point of the circuitous groove (206) which is now filled with a dielectric material. In the embodiments where the conductive wafer is mounted on a sacrificial support material and the groove is cut through the wafer the support material may be removed by any appropriate process, e.g., grinding, chemical/mechanical polishing, acid etching, etc.

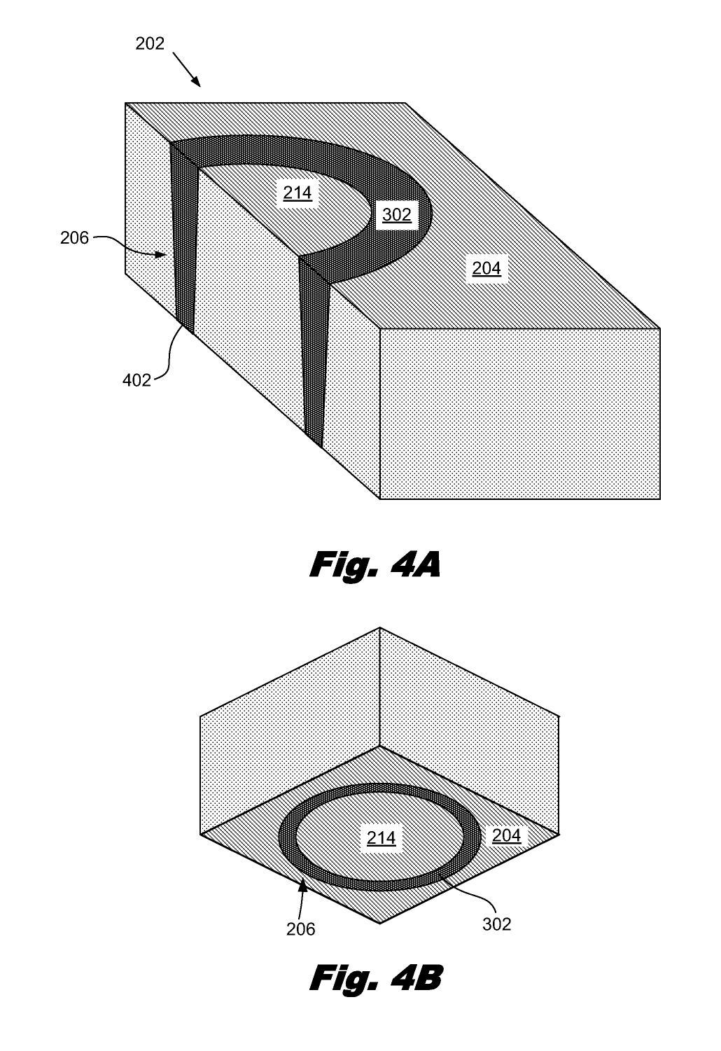

FIGS. 4A and 4B are diagrams showing an illustrative material removal step in the fabrication of the electrical feedthrough. In this step, the bottom surface of the monolithic slab (202) has been removed to expose the dielectric material at the bottom of the circuitous groove.

The material removal process may be any grinding, polishing, or other material removal process which removes the bottom surface of the monolithic slab without compromising the resulting hermetic seal. For example, lapping or chemical mechanical polishing may be used to remove material from the surfaces of the monolithic slab (202). After the grinding process is complete, the pin (208) will be transformed into a pin (214) which is completely electrically isolated from the rest of the monolithic wafer. That is, a voltage applied to the pin (214) will cause current to flow through the pin (214), but no significant current will flow through the remainder of the feedthrough.

The top surface of the monolithic slab (202) may also be ground down to remove any excess material or undesirable surface films and to create a smooth surface. Excess material may be created by whatever process was used to create the dielectric material. For example, if a thermal oxidation process was used, a metal oxide layer on top of the surface of the monolithic slab can be removed to expose the conductive upper surface of the pins.

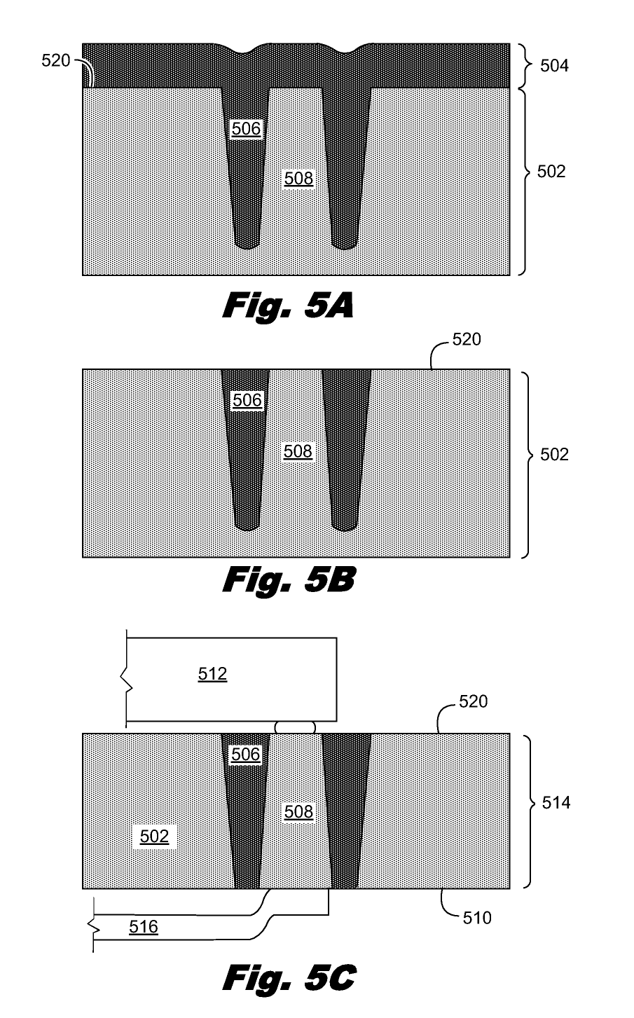

FIGS. 5A-5C are cross-sectional diagrams showing illustrative steps in a fabrication process to form a hermetic feedthrough. FIG. 5A is a cross-sectional view of a groove engraved into a monolithic slab (502) which has been filled with a dielectric material (506). In this illustrative embodiment, the dielectric material (506) has been deposited through a process such as anodizing or electrophoretic deposition. This forms a pin (508) which is surrounded by dielectric material (506) on all sides except for its bottom surface. In some embodiments, this deposition process may also leave an unwanted layer (504) on the upper surface (520) of the monolithic slab (502).

FIG. 5B is a cross-sectional view of the monolithic slab (502) after the unwanted dielectric material (504) is removed from the upper surface (520). At this point the upper surface of the pin (508) is exposed.

FIG. 5C is a cross-sectional view of the monolithic slab after its bottom surface (510) has been ground down to expose the dielectric material (508) at the bottom of the groove. The monolithic slab (502) is now configured to be used as a hermetic feedthrough (514). Removal of the material from the bottom surface (510) of the monolithic slab (502) electrically isolates the pin (508) from the surrounding material of the monolithic slab (502). At this or earlier stage in the process, additional steps may be performed to improve the structural or electrical characteristics of the dielectric material (506). For example, steps may be taken to cause the densification, pore filling, or sintering of the dielectric material. For example, firing of a sol gel, slurry, or electrophoresis deposited dielectric material can significantly improve the strength, hardness, and impermeability of the dielectric material.

Where the monolithic slab (502) is a metallic material, the firing process can be advantageously used to anneal all or portions of the monolithic slab (502). For example, where the monolithic slab (502) is a titanium wafer, the firing process may exceed 800 C. At temperatures near 800 C., titanium or titanium alloys may undergo a phase transition from an alpha phase to a beta phase. The composition of the titanium alloys can raise or lower the temperature at which this transition takes place. In general, the alpha phase is stronger but less ductile than the beta-phase. By selectively heating, cooling, and/or depositing additives during the firing process, the state of the titanium wafer can be adjusted over one or more regions. Further, the firing process can be altered to control the grain regrowth and recrystallization within the titanium wafer.

Modification of the monolithic slab to enhance the properties of the final feedthrough or ease of processing may take place before or after the formation of the circuitous groove in the slab. These processes include, but are not limited to sacrificial layers placed on the top and/or bottom of the feedthrough to prevent the formation of undesirable films or improve the release of films on the surfaces of feedthrough, a doping layer added to the circuitous groove to plasticize the titanium, or a doping layer to improve the adhesion of the dielectric film.

After the construction of the feedthrough (514) is complete, the feedthrough (514) can be integrated into the hermetic case. First, the electrical components (512) may be mounted on the upper surface (520) of the feedthrough (514) so that the electrical components are properly connected to the various pins (508). Then the perimeter of the feedthrough (514) is connected to other components of the outer case (108, FIG. 1). This connection is impermeable to both gas and fluid.

The electrical connections (516) between exterior components are then made with the bottom surface of the pins (508). This allows the electrical components (512) in the interior to receive power and signals, as well as to output electrical signals.

According to one illustrative embodiment, both the outer case of the implant and the hermetic feedthrough are made from titanium or a titanium alloy. This may provide a number of advantages. For example, making a hermetic connection between the feedthrough and the case is relatively straightforward because the two materials are the same. For example, the feedthrough may be laser welded into the outer case. Additionally, there is no thermal mismatch between the feedthrough and the case. Consequently, the feedthrough and the case expand and contract together, which reduces the likelihood that the joint will be compromised by thermal cycling.

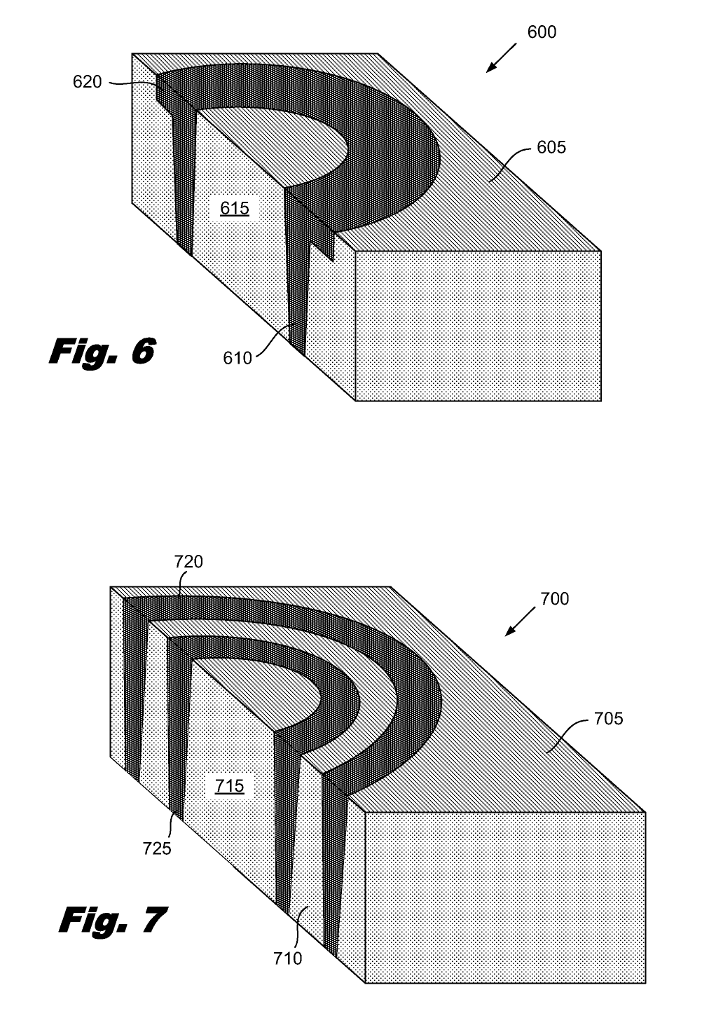

The circuitous groove, which is filled with dielectric material, could have a variety of geometries. FIG. 6 is a cut-away perspective view of a hermetic feedthrough (600) which has an extended insulating area (620). According to one illustrative embodiment, the hermetic feedthrough (600) includes a circuitous groove (610) and a central pin (615). The circuitous groove (610) has been widened on the top side of the monolithic slab (605) to produce the extended insulating area (620). The extended insulating area (620) can be desirable for a variety of reasons. For example, the extended insulating area (620) decreases the precision with which electronic components must be placed over the pin. Greater misalignments of the contact pads of the electronic components could be accommodated without the contact pads being shorted to the surrounding metal. The extended insulating area could be formed in a wide variety of shapes which are only limited by the process constraints and the desired operation of the device.

FIG. 7 is a cut-away perspective view of a hermetic feedthrough (700) which incorporates multiple circuitous grooves (720, 725) to produce concentric conductive paths (710, 715). According to one illustrative embodiment, the circuitous groove (725) creates a central pin (715) which is surrounded by a shielding conductor (710). This coaxial configuration could protect an electrical signal transmitted over the central pin (715) from external electromagnetic interference and prevent the leakage of the electrical signal into other adjacent signals. This could be particularly important in transmitting higher frequency signals.

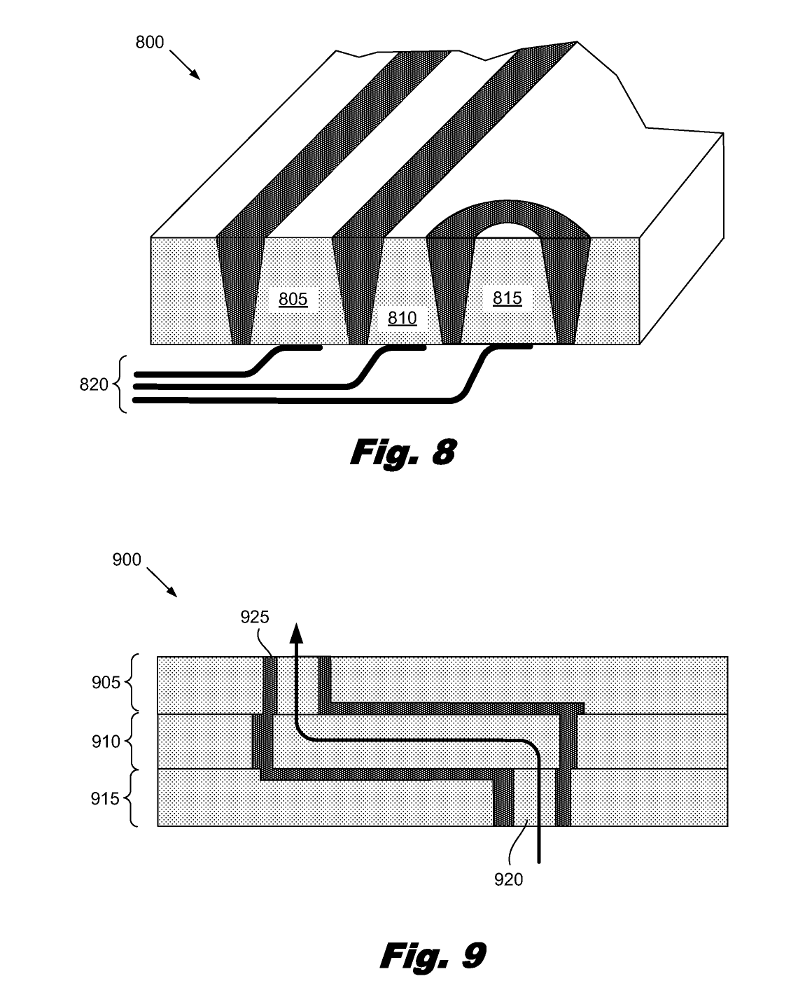

FIG. 8 is a cut-away perspective view of a portion of an illustrative hermetic feedthrough (800) which includes a variety of pin geometries. As discussed above the circuitous grooves may be formed in any geometry that completely encompasses a central pin. In this illustrative embodiment, a long rectangular pin (805) has been formed in the hermetic feedthrough. This long rectangular pin (805) may be used for a variety of applications, such as a power bus for multiple electronic devices or signal routing. A hermetic feedthrough may include the long rectangular pin (805) in combination with pins have a variety of other geometries such as a circular pin (815). In some configurations it may be advantageous to make electrical connections to portions (810) of the monolithic slab which surround the pins (805, 815). For example, the surrounding portions (810) the monolithic slab may be electrically grounded. A plurality of wires (820) connects to the various areas of the hermetic connector (800) and provides electrical access to the interior of the hermetically sealed compartment.

FIG. 9 is a cross-sectional view of an illustrative multilayer hermetic feedthrough (900). In this illustrative embodiment, three layers (905, 910, 915) have been combined to form a serpentine conductive path (920) which is surrounded by dielectric material (925). Each of the three layers (905, 910, 915) can be formed from monolithic slabs using the techniques discussed above. Extended insulating areas can be etched into the slabs to create the dielectric insulation.

According to one illustrative embodiment, the serpentine conductive path (920) and layers (905, 910, 915) may be diffusion bonded. In general, diffusion bonding is performed by pressing two work pieces together at an elevated temperature. Atoms migrate across the joint, forming a bond between the work pieces. Where the layers (905, 910, 915) are composed from titanium, diffusion bonding may be a particularly attractive option for joining the layers and conductive path.

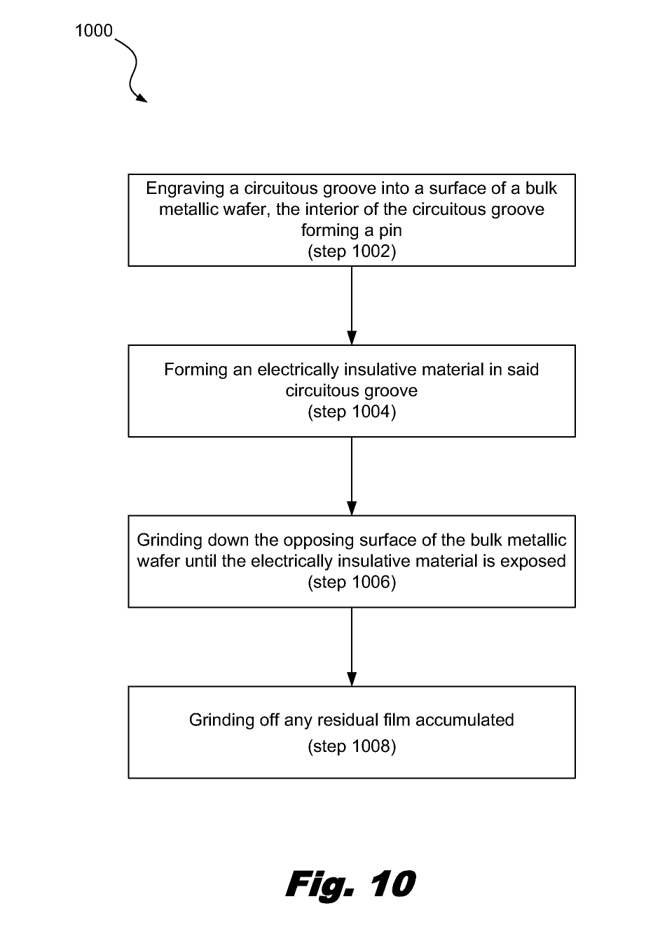

FIG. 10 is a flowchart (1000) showing an illustrative method for fabricating an electrically isolated pin in a monolithic wafer. According to one illustrative embodiment, a method for fabricating an electrical feedthrough may include engraving (step 1002) a circuitous groove into a surface of a monolithic metallic wafer, an interior of the circuitous groove forming a pin, the circuitous groove being engraved less than completely through to an opposing surface of the metallic wafer, forming (step 1004) an dielectric material in the circuitous groove, grinding (step 1006) down an opposing surface to the surface until the dielectric material is exposed, and removing (step 1008) any residual film accumulated on the surface of the metallic wafer. The residual film may be generated by a variety of processes, including the deposition of the dielectric material, firing process, or other process. This residual film may be removed by any suitable process, including chemical etching or mechanical removal processes.

The previously described figures are not necessarily drawn to scale. Additionally, they do not limit the precise form of groove, dielectric material, or metallic material.

In sum, an electrical feedthrough may be formed by creating an electrically isolated pin into a metallic wafer. The pin may be formed by engraving a circuitous groove into the surface of the metallic slab. The groove is engraved less than all the way through to the other side of the metallic slab. A dielectric material may then be placed within the groove. The bottom of the metallic slab may then be ground down until the dielectric material is exposed. This process leaves a metallic pin surrounded by dielectric material.

In many cases, multiple pins may be formed into a single monolithic slab. Each pin is electrically isolated and may carry a separate electrical signal through the slab. Electrical feedthroughs embodying principles described herein may also allow for thinner casing for hermetically sealed devices. In addition to use in implanted devices, these hermetic feedthroughs can be used in a variety of applications including vacuum systems, cryogenic systems, aircraft, missiles, spacecraft, or other devices.

The preceding description has been presented only to illustrate and describe embodiments and examples of the principles described. This description is not intended to be exhaustive or to limit these principles to any precise form disclosed. Many modifications and variations are possible in light of the above teaching.

What is claimed is:

1. A method for fabricating a hermetic electrical feedthrough, the method comprising:
engraving a circuitous groove into a surface of an electrically conductive monolithic slab, an interior of said circuitous groove forming a pin;
forming a dielectric material in said circuitous groove; and
electrically isolating the pin from surrounding material.

2. The method of claim 1, in which said circuitous groove is formed less than completely through to an opposing surface of said monolithic slab.

3. The method of claim 2, in which electrically isolating the pin from the surrounding metal comprises grinding down a side of the monolithic slab opposing said surface at least until said dielectric material is exposed.

4. The method of claim 1, in which said circuitous groove follows a closed path which entirely circumscribes a portion of said monolithic metallic slab.

5. The method of claim 1, in which said monolithic slab comprises a metallic material.

6. The method of claim 1, in which forming said dielectric material is done through at least one of the following: electrophoretic deposition, anodizing, deposition of a sol gel, casting a slurry/suspension solution, or thermal oxidation.

7. The method of claim 1, further comprising densification, pore filling, or sintering of the dielectric material.

8. The method of claim 1, further comprising coating, doping, alloying, or heat treating the monolithic slab.

9. The method of claim 1, further comprising:
fabricating a plurality of hermetic feedthroughs;
stacking the hermetic feedthroughs; and
bonding the hermetic feedthroughs together to create a multilayered hermetic electrical feedthrough.

10. The method of claim 1, further comprising laser welding the monolithic slab to a metallic case.

11. A hermetic electrical feedthrough comprising:
a monolithic metallic slab;
a circuitous groove cut completely through said monolithic metallic slab;
a dielectric material disposed within said circuitous groove; and
an electrically isolated portion of the monolithic metallic slab which is surrounded by the dielectric material.

12. The feedthrough of claim 11, in which said circuitous groove is a groove which forms a closed path which entirely circumscribes a portion of said monolithic metallic slab.

13. The feedthrough of claim 11, in which said dielectric material at least one of: an electrophoretically deposited material, a metal-oxide material, a solidified sol gel, a solidified slurry/suspension solution, and a thermal oxide.

14. The feedthrough of claim 13, in which said dielectric material is one of: a pore filled material, a densified material, or a sintered material.

15. A hermetically sealed implantable electronic enclosure comprising:
an outer casing; and
an electrical feedthrough comprising:
a monolithic metallic slab;
a circuitous groove cut completely through said metallic slab;
a dielectric material disposed within said circuitous groove to form an electrically isolated pin;
in which said electrical feedthrough is hermetically joined to said outer casing.

16. The enclosure of claim 15, in which said circuitous groove is a groove which forms a closed path which entirely circumscribes a portion of said monolithic metallic slab.

17. The enclosure of claim 15, in which said dielectric material is one of: an electrophoretically deposited material, a metal oxide, a solidified sol gel, a thermal oxide, and a solidified slurry/suspension solution.

18. The enclosure of claim 15, further comprising a plurality of said electrical feedthroughs; said plurality of electrical feedthroughs being stacked and bonded to create a multilayered hermetic electrical feedthrough.

19. The enclosure of claim 15, in which said monolithic slab is a titanium wafer and said outer case is titanium, and said monolithic slab is laser welded to said outer case.

20. The enclosure of claim 15, further comprising an electrical component within an interior of said enclosure, said electrical component configured to be operated through a voltage applied to said electrical feedthrough.
